(19) United States
(12) Patent Application Publication
(10) Pub. No.: US 2024/0381679 A1
(43) Pub. Date: Nov. 14, 2024

(54) MANUFACTURING METHOD OF PEROVSKITE LIGHT EMITTING DEVICE AND PEROVSKITE LIGHT EMITTING DEVICE MANUFACTURED THROUGH THE SAME

(71) Applicants: KOREA ADVANCED INSTITUTE OF SCIENCE AND TECHNOLOGY, Daejeon (KR); Seoul National University R&DB Foundation, Seoul (KR)

(72) Inventors: Byungha Shin, Daejeon (KR); JOONYUN KIM, Daejeon (KR); Jinu Park, Daejeon (KR); Yun Seog Lee, Seoul (KR); Young Ho Chu, Seoul (KR); Kijoon Bang, Seoul (KR); Sunggun Yoon, Seoul (KR); Ki Tae Park, Seoul (KR)

(21) Appl. No.: 18/660,977

(22) Filed: May 10, 2024

(30) Foreign Application Priority Data
May 11, 2023 (KR) 10-2023-0061208
May 9, 2024 (KR) 10-2024-0061420

(51) Int. Cl. H10K 50/11; H10K 50/15; H10K 71/18; H10K 85/10; H10K 85/50

(52) U.S. Cl. CPC H10K 50/11; H10K 71/18; H10K 50/15; H10K 85/111; H10K 85/1135; H10K 85/50

(57) ABSTRACT

A method of manufacturing a perovskite light emitting device using a two-dimensional material capable of implementing the entire visible light region as a light emitting material.

### CROSS-REFERENCE TO RELATED APPLICATION

This application claims priority to Korean Patent Application No. 10-2023-0061208 filed in the Korean Intellectual Property Office on May 11, 2023, and Korean Patent Application No. 10-2024-0061420 filed in the Korean Intellectual Property Office on May 9, 2024, and all the benefits accruing therefrom under 35 U.S.C. § 119, the entire contents of which are herein incorporated by reference.

### BACKGROUND OF THE INVENTION

### (a) Field of the Invention

A manufacturing method of a perovskite light emitting device and a perovskite light emitting device manufactured through the same are disclosed.

### (b) Description of the Related Art

A perovskite light emitting device, which is an electronic device using perovskite as a light emitting material, has advantages of achieving high photoelectric conversion efficiency, having a low manufacturing cost, applying a low temperature process and a low-cost solution process, and the like.

Herein, a radiative recombination rate of the light emitting material is related to exciton binding energy.

However, as the light emitting material, perovskite (ABX₃) with a three-dimensional crystal structure has limitations in spatial confinement of excitons formed within the material.

On the other hand, perovskite with a two-dimensional crystal structure, compared with the perovskite (ABX₃) with a three-dimensional crystal structure, smoothly implements the spatial confinement of excitons within the material and thus may be an ideal light emitting material.

However, a chalcogen-based two-dimensional material known to date, such as TMDC also has limitations in realizing a bandgap through its composition control.

### SUMMARY OF THE INVENTION

An embodiment provides a method of manufacturing a perovskite light emitting device using a two-dimensional material capable of implementing the entire visible light region as a light emitting material.

An embodiment provides a method of manufacturing a perovskite light emitting device using Ruddlesden-Popper perovskite (RPP) as a light emitting material.

Since the Rudelsden-Popper perovskite is a two-dimensional material capable of realizing the entire visible light region, it is more advantageous for producing light emitting devices than existing three-dimensional materials as well as chalcogen-based two-dimensional materials such as transition metal chalcogenides (TMD: Transition Metal Dichalcogenides).

### BRIEF DESCRIPTION OF THE DRAWINGS

FIG. 1 is a schematic view showing a perovskite light emitting device according to an embodiment.

FIG. 2 is a view showing the emission peak according to n of the Rudelsden-Popper perovskite according to an embodiment.

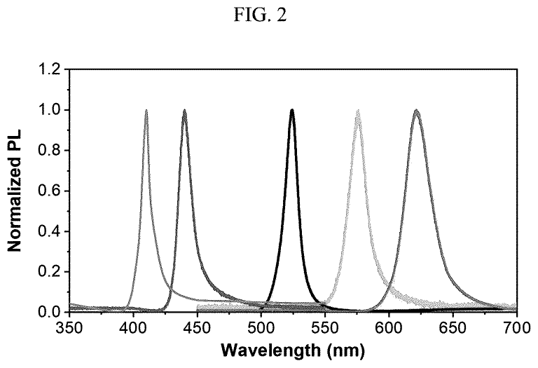

FIG. 3 is a schematic view showing a process for transferring and exfoliating a Rudelsden-Popper perovskite bulk single crystal layer according to an embodiment.

FIG. 4 is a view showing a color difference expressed according to the thickness of the exfoliated Rudelsden-Popper perovskite single crystal layer according to an embodiment.

FIG. 5 is a schematic view showing, from left to right, a structure formed by a process of transferring and exfoliating a Rudelsden-Popper perovskite bulk single crystal layer according to an embodiment.

FIG. 6 is a schematic view showing the process of completing a perovskite light emitting device after transferring and exfoliating a Rudelsden-Popper perovskite bulk single crystal layer according to an embodiment.

FIG. 7 is a schematic view showing a process for transferring and exfoliating a Rudelsden-Popper perovskite bulk single crystal layer using an adhesive material.

FIG. 8 is an optical microscope image of the result of transferring and exfoliating a Rudelsden-Popper perovskite bulk single crystal layer using an adhesive material.

FIG. 9 is an optical microscope image of the result of transferring and exfoliating the Rudelsden-Popper perovskite bulk single crystal layer on various lower substrates.

FIG. 10 is a view showing the current density (left) according to voltage and the luminance intensity (right) according to wavelength of the perovskite light emitting device of an embodiment.

### DETAILED DESCRIPTION OF THE EMBODIMENTS

Hereinafter, a perovskite light emitting device according to an embodiment of the present invention will be described in detail with reference to the attached drawings.

However, this is presented as an example, and the present invention is not limited thereby, and the present invention is only defined by the scope of the claims to be described later.

### Method for Manufacturing Perovskite Light Emitting Device

As previously described, the radiative recombination rate of a light emitting material is related to the exciton binding energy.

However, although it is a perovskite (ABX₃) with a three-dimensional crystal structure, there are limits to the spatial confinement of excitons formed within the material.

On the other hand, perovskite with a two-dimensional crystal structure is ideal as a light emitting material because the spatial confinement of excitons formed in the material is smooth compared to perovskite (ABX₃) with a three-dimensional crystal structure.

However, in the case of chalcogen-based two-dimensional materials such as TMDC known to date, the bandgap that can be realized through composition control is limited.

On the other hand, an embodiment of the present invention provides a method of manufacturing a perovskite light emitting device using Ruddlesden-Popper perovskite (RPP) as a light emitting material.

Specifically, in an embodiment, a method of manufacturing perovskite light emitting device includes preparing a first electrode on which a first functional layer is deposited; transferring a bulk single crystal layer of Ruddlesden-Popper perovskite (RPP) onto the first functional layer; exfoliating the transferred Rudelsden-Popper perovskite bulk single crystal layer to form an exfoliated Rudelsden-Popper perovskite single crystal layer; and sequentially depositing a second functional layer and a second electrode on the exfoliated Rudelsden-Popper perovskite single crystal layer, wherein one of the first functional layer and the second functional layer is an electron transport layer, and the other is a hole transport layer.

Since the Rudelsden-Popper perovskite is a two-dimensional material capable of realizing the entire visible light region, it is more advantageous for producing light emitting devices than existing three-dimensional materials as well as chalcogen-based two-dimensional materials such as transition metal chalcogenides (TMD: Transition Metal Dichalcogenides).

However, the Rudelsden-Popper perovskite may be obtained in a state of a bulk single crystal layer in which isotropic growth has occurred, resulting in low electrical conductivity in a Z-axis.

Accordingly, in order to apply the Rudelsden-Popper perovskite bulk single crystal layer to a light emitting device, it is necessary to make it into a thin film.

Accordingly, in an embodiment, a vertically stacked perovskite light emitting device is provided, including a process of transferring and exfoliating the Rudelsden-Popper perovskite bulk single crystal layer.

Hereinafter, the method for manufacturing the perovskite light emitting device of an embodiment will be described in detail.

### Rudelsden-Popper Perovskite Bulk Single Crystal Layer

The Rudelsden-Popper perovskite included in the Rudelsden-Popper perovskite bulk single crystal layer may be represented by Chemical Formula 1:

R₂Aₙ₋₁PbₙX₃ₙ₊₁ Chemical Formula 1

In Chemical Formula 1, R is a C1 to C30 alkyl ammonium cation; A is a cation selected from a methylammonium cation (MA⁺), a formamidinium cation (FA⁺), and a cesium cation (Cs⁺); X is a halogen selected from I, Br, and Cl; and n is an integer from 1 to 10.

As for perovskite (ABX₃) with a three-dimensional crystal structure, a bandgap is possible to control by mixing halide (i.e., using two or more types of halides as X).

In contrast, as for the Rudelsden-Popper perovskite, because the bandgap may be controlled by even not mixing the halide (i.e., even by using one type of halide as X), spectrum instability issues occurring in a case of mixing the halide may be solved.

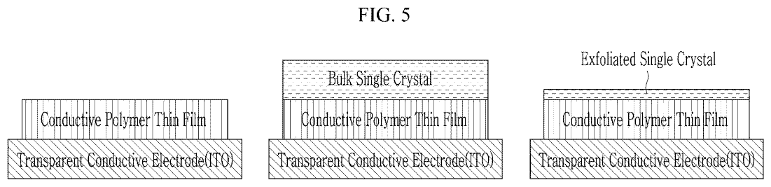

Specifically, through the photoluminescence peak and the full width at half maximum (FWHM) in Table 1 and FIG. 5, a light emitting material with various compositions capable of covering the entire visible light region may be secured by controlling n as well as using one type of halide as X.

TABLE 1

| | Photoluminescence | Photoluminescence |
|---|---|---|
| | peak | FWHM |
| PEA₂PbBr₄(X = Br, n = 1) | 409 nm | 11 nm |
| PEA₂MAPb₂Br₇(X = Br, n = 2) | 440 nm | 13 nm |
| PEA₂PbI₄(X = I, n = 1) | 524 nm | 14 nm |
| PEA₂MAPb₂I₇(X = I, n = 2) | 575 nm | 19 nm |
| PEA₂MA₂Pb₃I₁₀(X = I, n = 3) | 621 nm | 22 nm |

Transferring and exfoliating process of Rudelsden-Popper perovskite bulk single crystal layer

As previously mentioned, the Rudelsden-Popper perovskite can be obtained in the state of a bulk single crystal layer in which isotropic growth has occurred, and as a result, the electrical conductivity in the Z-axis may be low.

For this reason, in order to apply the Rudelsden-Popper perovskite bulk single crystal layer to a light emitting device, thinning is required.

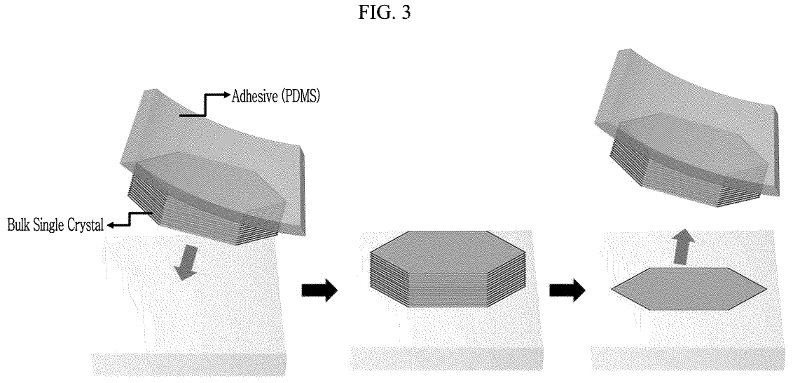

For this purpose, as shown in FIG. 3, the Rudelsden-Popper perovskite bulk single crystal layer of an embodiment is transferred and exfoliated.

Herein, compared with a case of simply mechanically exfoliating the Rudelsden-Popper perovskite bulk single crystal layer, in the case of transferring the Rudelsden-Popper perovskite bulk single crystal layer onto a first functional layer and exfoliating it, the exfoliated Rudelsden-Popper perovskite has a uniform thickness, uniform surface morphology, etc.

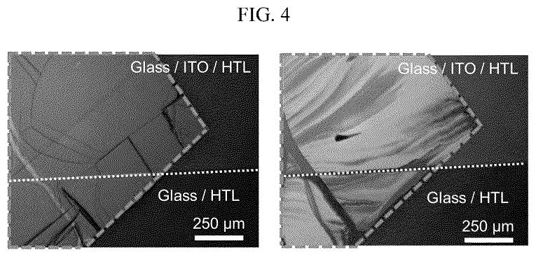

Herein, as shown in FIG. 4, the exfoliated Rudelsden-Popper perovskite single crystal layer exhibits color differences according to a thickness.

In addition, since the exfoliated Rudelsden-Popper perovskite single crystal layer itself becomes a light emitting layer, a vertically stacked perovskite light emitting device can be completed by stacking a second functional layer and a second electrode thereon.

### First Functional Layer (Lower Substrate for Transferring)

As shown in FIG. 5, in an embodiment, the first functional layer onto which the Rudelsden-Popper perovskite bulk single crystal layer is transferred is a hole transport layer, and the hole transport layer may be a hydrophilic conductive polymer thin film.

The hole transport layer may include a hydrophilic conductive polymer such as PEDOT:PSS, 3-hydroxytyramine hydrochloride (DA·HCl), poly[bis(4-butypheny)-bis(phenyl)benzidine (poly-TPD), poly(9-vinylcarbazole) (PVK); and NiOₓ, MoO₃, and Cu₂O as inorganic substances; or a combination thereof.

The hole transport layer may include γ-aminobutyric acid (GABA), Zwitterion, 3-glycidyloxypropyl) trimethoxysilane (GOPS), or a combination thereof as an additive.

Since the hydrophilic conductive polymer thin film is a rigid substrate, cracking of the Rudelsden-Popper perovskite bulk single crystal layer transferred to the surface is suppressed.

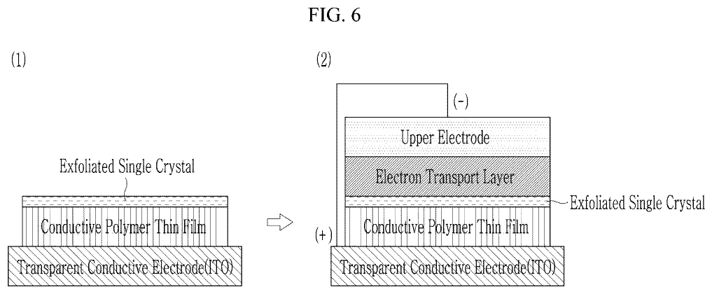

In addition, since the hydrophilic “conductive” polymer thin film has conductivity, as shown in FIG. 6, a vertically stacked perovskite light emitting device can be completed by stacking a second functional layer and a second electrode on the exfoliated Rudelsden-Popper perovskite single crystal layer.

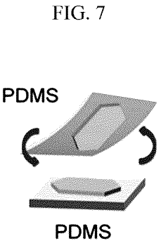

As shown in FIG. 7, if an adhesive material (e.g., PDMS) is used as a lower substrate to transfer the Rudelsden-Popper perovskite bulk single crystal layer, the yield of the exfoliating area is reduced.

Specifically, this is because cracks easily occur in the Rudelsden-Popper perovskite bulk single crystal layer transferred to the surface due to the surface curvature of the lower substrate.

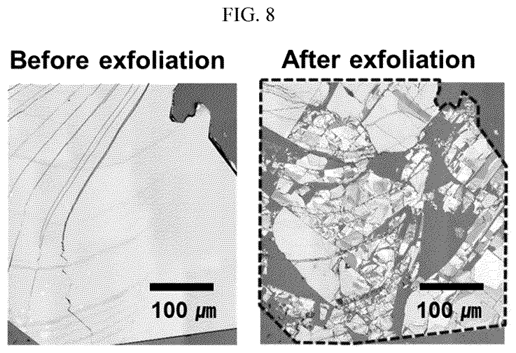

This is as shown in FIG. 8.

### Adhesive Substances (Substances Used for Exfoliating)

Previously, for large-area exfoliation of two-dimensional materials grown in bulk, the so-called metal assisted exfoliation technology has been used to induce stress inside the two-dimensional bulk by depositing a metal layer such as gold (Au).

In this case, a process of additionally removing the metal layer from the surface of the two-dimensional material is required after exfoliating, but since perovskite materials are unstable to moisture and chemical treatment, it is difficult to introduce a metal etchant to additionally remove the metal layer.

In other words, it is difficult to remove additional metal layers without damaging the perovskite material.

On the other hand, in an embodiment, the Rudelsden-Popper perovskite bulk single crystal layer transferred onto the hydrophilic conductive polymer thin film can be easily exfoliated off using an adhesive material without damaging the perovskite material.

In particular, in an embodiment, the exfoliating process using an adhesive material is possible because the “hydrophilic” conductive polymer thin film among the conductive polymer thin films is used as the lower substrate.

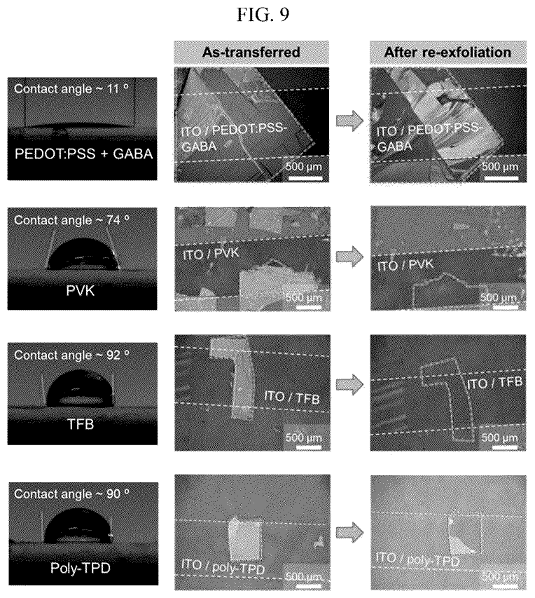

This is as shown in FIG. 9.

The adhesive material is not particularly limited, but may include polydimethylsiloxane (PDMS).

### Perovskite Light Emitting Device

In another embodiment, a perovskite light emitting device includes a first electrode 1; a first functional layer 2 on the first electrode; an exfoliated Rudelsden-Popper perovskite single crystal layer 3 on the second functional layer; a second functional layer 4 on the exfoliated Rudelsden-Popper perovskite single crystal layer; and a second electrode 5 on the second functional layer, wherein one of the first functional layer and the second functional layer is an electron transport layer, and the other is a hole transport layer.

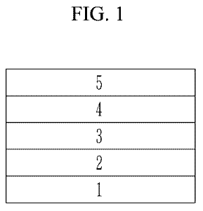

FIG. 1 is a view schematically showing a perovskite light emitting device of an embodiment, which includes both forward and reverse structures.

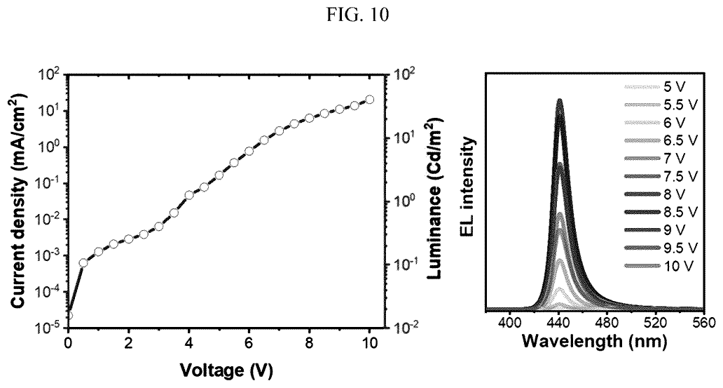

In addition, FIG. 10 is a view showing the current density (left) according to voltage and the luminance intensity (right) according to wavelength of the perovskite light emitting device of an embodiment.

### Exfoliated Rudelsden-Popper Perovskite Single Crystal Layer

The exfoliated Rudelsden-Popper perovskite single crystal layer may have a surface rms of 1 Å or less, specifically 0.5 Å or less.

The exfoliated Rudelsden-Popper perovskite single crystal layer may have a thickness of 20 to 30 nm.

The color of the exfoliated Rudelsden-Popper perovskite single crystal layer varies depending on its thickness.

Accordingly, the exfoliated Rudelsden-Popper perovskite single crystal layer can function as a light emitting layer.

According to an embodiment, the first electrode may include one selected from FTO, ITO, IZO, ZnO—Ga₂O₃, ZnO—Al₂O₃, SnO₂—Sb₂O₃, and a combination thereof, but is limited thereto.

The second electrode may include one selected from Au, Ag, Pt, Ni, Cu, In, Ru, Pd, Rh, Mo, Ir, Os, C, a conductive polymer, and a combination thereof, but is not limited to this.

One of the first functional layer and the second functional layer may be an electron transport layer, and the other may be a hole transport layer.

The hole transport layer may be PEDOT:PSS, 3-hydroxytyramine hydrochloride (DA·HCl), poly[bis(4-butypheny)-bis(phenyl)benzidine (poly-TPD), and poly(9-vinylcarbazole) (PVK) as a hydrophilic conductive polymer; NiOₓ, MoO₃, and Cu₂O as an inorganic material; or a combination thereof.

The hole transport layer may include γ-aminobutyric acid (GABA), Zwitterion, 3-glycidyloxypropyl) trimethoxysilane (GOPS), or a combination thereof as an additive.

The electron transport layer includes one selected from SnO₂, TiO₂, ZrO, Al₂O₃, ZnO, WO₃, Nb₂O₅, and TiSrO₃ as an inorganic material; phenyl-C61-butyric acid methyl ester (PCBM), 2,2′,2″-(1,3,5-benzinetriyl)-tris(1-phenyl-1-H-benzimidazole (TPBi), C60, bathocuproine (BCP), 4,6-bis(3,5-di(pyridin-3-yl)phenyl)-2-methylpyrimidine (B3PyMPM), tris(2,4,6-trimethyl-3-(pyridin-3-yl)phenyl)borane (3TPYMB), 2-(4-biphenyl)-5-(4-tert-butylphenyl)-134-oxadiazole (PBD), bis[2-(diphenylphosphino)phenyl]ether oxide (DPEPO) as an organic material; and combinations thereof, but is not limited thereto.

Hereinafter, examples of the present invention and comparative examples are described.

The following examples are only examples of the present invention, but the present invention is not limited to the following examples.

### Example 1 (RPP=PEA₂MAPb₂Br₇)

(1) Preparation of the First Electrode on which the First Functional Layer (Hole Transport Layer) is Deposited

For the first electrode, a transparent electrode ITO with a thickness of 150 nm and a width of 1 mm is deposited on a 1.5 cm×1.5 cm glass substrate.

Then, the substrate is washed using deionized water (DI water), acetone, and isopropyl alcohol (IPA).

30 nm of PEDOT:PSS is deposited as the first functional layer (hole transport layer) using spin coating.

### (2) Transferring of Rudelsden-Popper Perovskite Bulk Single Crystal Layer

The synthesized Rudelsden-Popper perovskite bulk single crystal is placed on polydimethylsiloxane (PDMS), adhered to face the new PDMS, and then separated from each other to obtain a bulk single crystal with a size of about several um.

The bulk single crystal mounted on PDMS is transferred onto the first functional layer by physically attaching it to a substrate on which the first functional layer is deposited on the first electrode and then removing it.

### (3) Exfoliation of the Transferred Rudelsden-Popper Perovskite Bulk Single Crystal Layer

A Rudelsten-Popper perovskite single crystal with a thickness of 45 nm is fabricated by further exfoliation of the transferred bulk single crystal onto the first functional layer using a new PDMS.

### (4) Deposition of the Second Functional Layer (Electron Transport Layer) and the Second Electrode

TPBi is deposited to be 25 nm-thick as a second functional layer (ETL), and LiF and Al are respectively deposited to be 1 nm-thick and 100 nm-thick as a second electrode are deposited under a vacuum degree of 10⁻⁶ torr or less by using a thermal depositor.

### Example 2

An exfoliation process of a Rudelsden-Popper perovskite bulk single crystal layer additionally proceeds to form a Rudelsden-Popper perovskite single crystal layer with a thickness of 36 nm.

Except for this, a perovskite light emitting device is manufactured in the same manner as in Example 1.

### Example 3

An exfoliation process of a Rudelsden-Popper perovskite bulk single crystal layer additionally proceeds to form an exfoliated Rudelsden-Popper perovskite single crystal layer with a thickness of 30 nm.

Except for this, a perovskite light emitting device is manufactured in the same manner as in Example 1.

### Example 4

An exfoliation process of a Rudelsden-Popper perovskite bulk single crystal layer additionally proceeds to form an exfoliated Rudelsden-Popper perovskite single crystal layer with a thickness of 28 nm.

Except for this, a perovskite light emitting device is manufactured in the same manner as in Example 1.

### Example 5

An exfoliation process of a Rudelsden-Popper perovskite bulk single crystal layer additionally proceeds to form an exfoliated Rudelsden-Popper perovskite single crystal layer with a thickness of 25 nm.

Except for this, a perovskite light emitting device is manufactured in the same manner as in Example 1.

### Example 6

An exfoliation process of a Rudelsden-Popper perovskite bulk single crystal layer additionally proceeds to form an exfoliated Rudelsden-Popper perovskite single crystal layer with a thickness of 21 nm.

Except for this, a perovskite light emitting device is manufactured in the same manner as in Example 1.

### Example 7

An exfoliation process of a Rudelsden-Popper perovskite bulk single crystal layer additionally proceeds to form an exfoliated Rudelsden-Popper perovskite single crystal layer with a thickness of 14 nm.

Except for this, a perovskite light emitting device is manufactured in the same manner as in Example 1.

### Comparative Example 1

(1) Preparation of the First Electrode on which the First Functional Layer (Hole Transport Layer) is Deposited

For the first electrode, a transparent electrode ITO with a thickness of 150 nm and a width of 1 mm is deposited on a 1.5 cm×1.5 cm glass substrate.

Then, the substrate is washed using deionized water (DI water), acetone, and isopropyl alcohol (IPA).

30 nm of PEDOT:PSS is deposited as the first functional layer (hole transport layer) using spin coating

### (2) Transferring of Rudelsden-Popper Perovskite Bulk Single Crystal Layer

The synthesized Rudelsden-Popper perovskite bulk single crystal is placed on polydimethylsiloxane (PDMS), adhered to face the new PDMS, and then separated from each other to obtain a bulk single crystal with a size of about several um.

The bulk single crystal mounted on PDMS is transferred onto the first functional layer by physically attaching it to a substrate on which the first functional layer is deposited on the first electrode and then removing it.

### (3) Deposition of the Second Functional Layer (Electron Transport Layer) and the Second Electrode

TPBi is deposited to be 25 nm-thick as a second functional layer (ETL), and LiF is deposited to be 1 nm-thick and Al is deposited to be 100 nm-thick as a second electrode under a vacuum degree of 10⁻⁶ torr or less by using a thermal depositor.

### Evaluation Example 1: Evaluation of Light Emitting Device

The light emitting devices of Examples 1 to 7 and Comparative Example 1 are evaluated in the following method, and the evaluation results are shown in Table 2.

Current density: When each of the light emitting devices exhibits the highest luminous efficiency by applying a voltage of 0 to 10 V thereto, its current density is measured.

Maximum luminous efficiency: When the voltage of 0 to 10 V is applied to each of the light emitting devices, its highest luminous efficiency is measured.

Full width at half maximum (FWHM) of light emitting spectrum: After measuring a spectrum of light emitted from each of the light emitting devices, a full width at half maximum (FWHM) of the spectrum is measured.

TABLE 2

| | | | Light |
|---|---|---|---|
| | | Maximum | emitting full |
| | Current | luminous | width at |
| | density | efficiency | half maximum |
| | (mA/cm²) | (%) | (FWHM) (nm) |
| Example 1 | 21.68 | 0.00169 | 14 |
| Example 2 | 13.47 | 0.00175 | 14 |
| Example 3 | 2.05 | 0.009 | 14 |
| Example 4 | 4.38 | 0.01 | 14 |
| Example 5 | 2.93 | 0.0016 | 14 |
| Example 6 | 6.94 | 0.00065 | 14 |
| Example 7 | 8.5 | 0.0016 | 14 |
| Comparative | Not emitting | Not emitting | Not emitting |
| Example 1 | light | light | light |

What is claimed is:

1. A method of manufacturing perovskite light emitting device, comprising
preparing a first electrode including a first functional layer;
transferring a bulk single crystal layer of Ruddlesden-Popper perovskite (RPP) onto the first functional layer;
exfoliating the transferred Rudelsden-Popper perovskite bulk single crystal layer to provide an exfoliated Rudelsden-Popper perovskite single crystal layer; and
sequentially depositing a second functional layer and a second electrode on the exfoliated Rudelsden-Popper perovskite single crystal layer,
wherein one of the first functional layer or the second functional layer is an electron transport layer and the other is a hole transport layer.

2. The method of claim 1, wherein
the Rudelsden-Popper perovskite is represented by Chemical Formula 1,
R₂Aₙ₋₁PbₙX₃ₙ₊₁ Chemical Formula 1
wherein, in Chemical Formula 1,
R is a C1 to C30 alkyl ammonium cation;
A is a cation selected from a methylammonium cation (MA⁺), a formamidinium cation (FA⁺), or a cesium cation (Cs⁺);
X is a halogen selected from I, Br, or Cl; and
n is an integer from 1 to 10.

3. The method of claim 1, wherein
the first functional layer is a hole transport layer, and
the hole transport layer is hydrophilic conductive polymer thin film.

4. The method of claim 3, wherein
the hole transport layer comprises
PEDOT:PSS, 3-hydroxytyramine hydrochloride (DA·HCl), poly[bis(4-butypheny)-bis(phenyl)benzidine (poly-TPD), or poly(9-vinylcarbazole) (PVK), or a combination thereof, as a hydrophilic conductive polymer;
NiOₓ, MoO₃, or Cu₂O or a combination thereof as an inorganic material; or
a combination thereof.

5. The method of claim 3, wherein
the hole transport layer comprises γ-aminobutyric acid (GABA), zwitterion, 3-glycidyloxypropyl) trimethoxysilane (GOPS), or a combination thereof.

6. The method of claim 1, wherein
the exfoliating of the transferred Rudelsden-Popper perovskite bulk single crystal layer is performed using an adhesive material.

7. The method of claim 6, wherein
the adhesive material comprises polydimethylsiloxane (PDMS).

8. A perovskite light emitting device, comprising
a first electrode;
a first functional layer disposed on the first electrode;
an exfoliated Rudelsden-Popper perovskite single crystal layer 3 disposed on the first functional layer;
a second functional layer disposed on the exfoliated Rudelsden-Popper perovskite single crystal layer; and
a second electrode on the second functional layer,
wherein one of the first functional layer or the second functional layer is an electron transport layer and the other is a hole transport layer.

9. The perovskite light emitting device of claim 8, wherein
exfoliated Rudelsden-Popper perovskite single crystal layer has a surface rms of 1 Å or less.

10. The perovskite light emitting device of claim 8, wherein
the exfoliated Rudelsden-Popper perovskite single crystal layer has a thickness of 20 nm to 30 nm.
